(19) United States
(12) Patent Application Publication
(10) Pub. No.: US 2026/0206281 A1
(43) Pub. Date: Jul. 16, 2026

(54) SEMICONDUCTOR STRUCTURE INCLUDING DEEP BACK SIDE VIA AND METHOD FOR MANUFACTURING THE SAME

(71) Applicant: TAIWAN SEMICONDUCTOR MANUFACTURING COMPANY, LTD., Hsinchu (TW)

(72) Inventors: Ming-Heng TSAI, Hsinchu (TW); Ta-Chun LIN, Hsinchu (TW)

(73) Assignee: TAIWAN SEMICONDUCTOR MANUFACTURING COMPANY, LTD., Hsinchu (TW)

(21) Appl. No.: 19/020,761

(22) Filed: Jan. 14, 2025

(51) Int. Cl. H10D 64/23; H10D 64/01; H10D 84/01; H10D 84/83

(52) U.S. Cl. CPC H10D 64/256; H10D 64/01; H10D 84/0153; H10D 84/832

(57) ABSTRACT

A method for manufacturing a semiconductor structure includes: forming a channel portion including a distal channel feature and a proximal channel feature on a front side of a substrate; forming a first source/drain portion and a second source/drain portion which are respectively disposed at two opposite sides of the channel portion; forming a first front contact which extends into the first source/drain portion through a front surface of the first source/drain portion; and forming a back contact which extends into the second source/drain portion through a back surface of the second source/drain portion. A first distance between the substrate and a distal surface of the back contact is greater than a second distance between the substrate and a distal surface of the proximal channel feature.

### BACKGROUND

In order to manufacture integrated circuits (ICs) with enhanced performance, reduction in critical dimension (CD) of transistors and effective power routing in the ICs are essential. However, reduction in critical dimension of transistors often leads to elevated contact resistance, which may adversely affect overall device performance. Therefore, various approaches are being continuously developed to optimize components of the transistors so as to achieve a balance between reduction in CD, minimization of contact resistance, and routing efficiency in the ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 28 are schematic views illustrating intermediate stages of the method for manufacturing the semiconductor structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost,” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

Source/drain portion(s) may refer to a source or a drain, individually or collectively dependent upon the context.

In order to increase front side routing resource for a semiconductor device, a power routing (which may include super power rails, such as supply lines (Vdd) and ground lines (Vss)) may be moved to a back side of a substrate and is connected to the semiconductor device through back side vias. However, the back side vias extending through the substrate and terminating at back portions of source/drain regions might cause such back side vias to have high contact resistance to front portions of the source/drain regions due to insufficient contact area, resulting in elevated parasitic resistance from the back portions of the source/drain regions formed with the back side vias to the front portions of the source/drain regions formed with nanosheet channels. Therefore, the present disclosure is directed to a semiconductor structure including a back side via which extends deep into a source/drain portion, and a method for manufacturing the same. The semiconductor structure may be a field effect transistor (FET) such as a planar FET transistor, a nanosheet transistor (e.g., a gate-all-around (GAA) nanosheet transistor, a forksheet nanosheet transistor, and a complementary FET (CFET) nanosheet transistor), but is not limited thereto. The semiconductor structure may be configured as an n-type metal-oxide-semiconductor FET (MOSFET) or p-type MOSFET. In the following description, a distal surface and a proximal surface mean two surfaces of an element, which are distal from and proximal to a substrate, respectively, and an uppermost one and a bottommost one of elements means one of the elements which are most distal from and most proximal to the substrate, respectively. The back side via extends deep into the source/drain portion until a distance between a substrate and a distal surface of the back side via is larger than a distance between the substrate and a distal surface of a shallow trench isolation (STI) and is also larger than a distance between the substrate and a distal surface of a bottommost one of the channel features. Thus, the back side via has a relatively large contact area to the source/drain portion so as to reduce distance of current travelling to reach the channel features, thereby reducing contact resistance to the source/drain portion. Therefore, parasitic resistance can be reduced to enhance performance of the semiconductor structure.

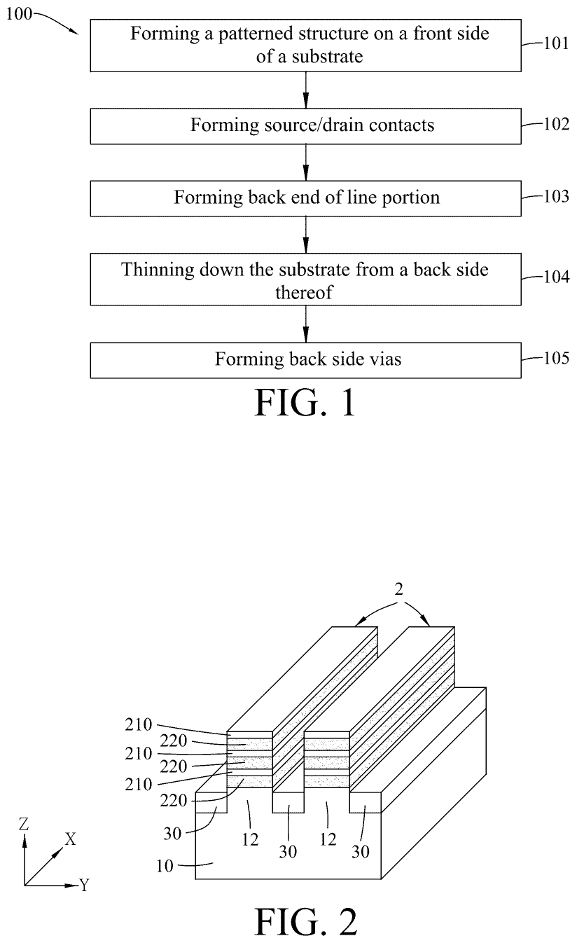

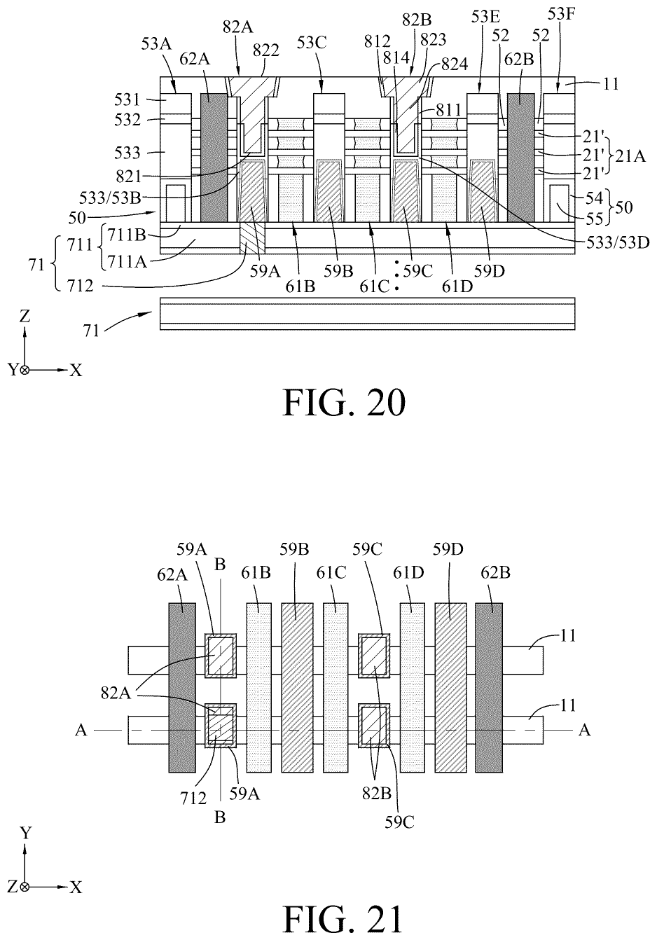

FIG. 1 is a flow diagram illustrating a method 100 for manufacturing the semiconductor structure (for example, the semiconductor structures respectively shown in FIG. 20 to 28) in accordance with some embodiments. FIGS. 2 to 28 illustrate schematic views of intermediate stages of the method 100 in accordance with some embodiments. Some repeating structures are omitted in FIGS. 2 to 28 for the sake of brevity. Additional steps can be provided before, after or during the method 100, and some of the steps described herein may be replaced by other steps or be eliminated.

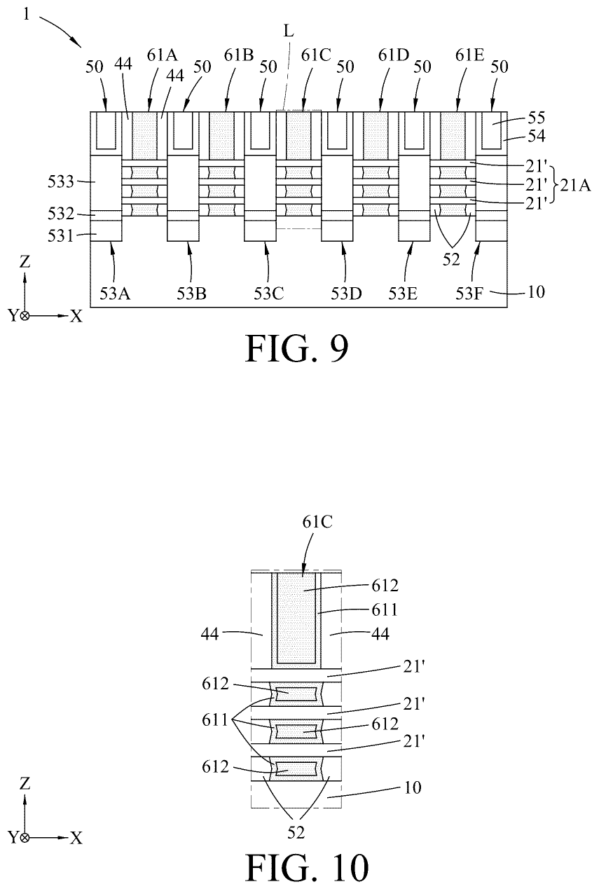

Referring to FIG. 1 and the examples illustrated in FIGS. 2 to 10, the method 100 begins at step 101, where a patterned structure 1 (see FIG. 9) is formed on a front side of a substrate 10.

The substrate 10 may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The substrate 10 may be doped with p-type impurities or n-type impurities, or undoped. In addition, the substrate 10 may be a bulk silicon substrate, a silicon-on-insulator (SOI) substrate, or a germanium-on-insulator (GOI) substrate. In some embodiments, the substrate 10 may be made of silicon. Other suitable materials for forming the substrate 10 are within the contemplated scope of the present disclosure.

Referring to FIG. 2, step 101 may include a first sub-step of forming fins 12 and nanosheet material stacks 2 respectively stacked on the fins 12. The fins 12 are disposed on a substrate 10 and spaced apart from each other in a transverse direction (Y) by a distance ranging from about 15 nm to about 60 nm, but is not limited thereto. Each of the fins 12 extends and is elongated in a longitudinal direction (X) transverse to (e.g., perpendicular to) the transverse direction (Y). The nanosheet material stacks 2 are respectively disposed on the fins 12 opposite to the substrate 10 in a vertical direction (Z) transverse to (e.g., perpendicular to) the transverse direction (Y) and the longitudinal direction (X). In some embodiments, formation of the fins 12 and the nanosheet material stacks 2 may include: forming a lamination structure (not shown) on a starting substrate (not shown) by a deposition process; and patterning the lamination structure and the starting substrate using a patterning process. In some embodiments, the lamination structure include multiple layers (not shown) for forming the nanosheet material stacks 2 and a masking layer (not shown) disposed over the multiple layers. As a result, the lamination structure is patterned into the nanosheet material stacks 2 and masking regions (not shown) respectively disposed on the nanosheet material stacks 2, and the starting substrate is patterned into the substrate 10 and the fin 12. The deposition process may include, such as physical vapor deposition (PVD), chemical vapor deposition (CVD), atomic layer deposition (ALD), or the likes, or combinations thereof, but are not limited thereto. The patterning process may include a photolithography process, followed by an etching process. The photolithography process may include: forming a photoresist layer over a structure to be patterned by, e.g., spin coating; and patterning the photoresist layer using a photomask or without a mask (e.g., ion-beam writing). The etching process, which utilizes the patterned photoresist layer as an etching mask, may include etching the structure to be patterned by, for example, dry etching, wet etching, or a combination thereof. In the following description, a deposition process, a patterning process, a photolithography process or an etching process, unless otherwise stated or defined in this disclosure, may be performed in a way similar to the above-mentioned ones. Each of the nanosheet material stacks 2 includes first nanosheet layers 210 and second nanosheet layers 220 disposed to alternate with the first nanosheet layers 210 in the vertical direction (Z). The first nanosheet layers 210 are made of a first semiconductor material, and the second nanosheet layers 220 are made of a second semiconductor material different from the first semiconductor material. Possible materials for the first and second semiconductor materials are similar to those for the substrate 10, and thus details thereof are omitted for the sake of brevity. As shown in FIG. 2, in some embodiments, each of the nanosheet material stacks 2 includes three the first nanosheet layers 210, and three the second nanosheet layers 220. In other embodiments, a number of the first nanosheet layers 210 and a number of the second nanosheet layers 220 in each of the nanosheet material stacks 2 may be one, two, three, four or greater than four. In certain embodiments, the first nanosheet layers 210 include or are made of silicon, while the second nanosheet layers 220 include or are made of silicon germanium. Other suitable processes, materials and/or numbers for each of the first and second nanosheet layers 210, 220 are within the contemplated scope of the present disclosure.

The first sub-step may also include forming isolation elements 30 (see FIG. 2). Each of the isolation elements 30 are formed on the substrate 10 between two adjacent ones of the fins 12. Such isolation elements 30 may also be known as STI. The isolation elements 30 may be formed by: depositing an isolation material layer for forming the isolation elements 30 using any suitable deposition processes over the substrate 10 such that the isolation material layer fills spaces among the nanosheet material stacks 2; performing a planarization process (e.g., chemical mechanical polishing (CMP)) to obtain a planarized surface, through which the masking regions (not shown) remaining respectively on the nanosheet material stacks 2 may be exposed; etching back the isolation material layer using any suitable etch-back processes, such as dry etching, wet etching, anisotropic etching, or combinations thereof; and removing the masking regions. In the following description, an etch-back process, unless otherwise stated or defined in this disclosure, may be performed in a way similar to the above-mentioned ones. In some embodiments, a distance between the substrate 10 and a distal surface of each of the isolation elements 30 may be less than a distance between the substrate 10 and a distal surface of each of the fins 12. In some embodiments, the isolation elements 30 include a dielectric material, such as an oxide-based dielectric (e.g., silicon oxide), but is not limited thereto. Other suitable processes, materials and/or configurations of the isolation elements 30 are within the contemplated scope of the present disclosure.

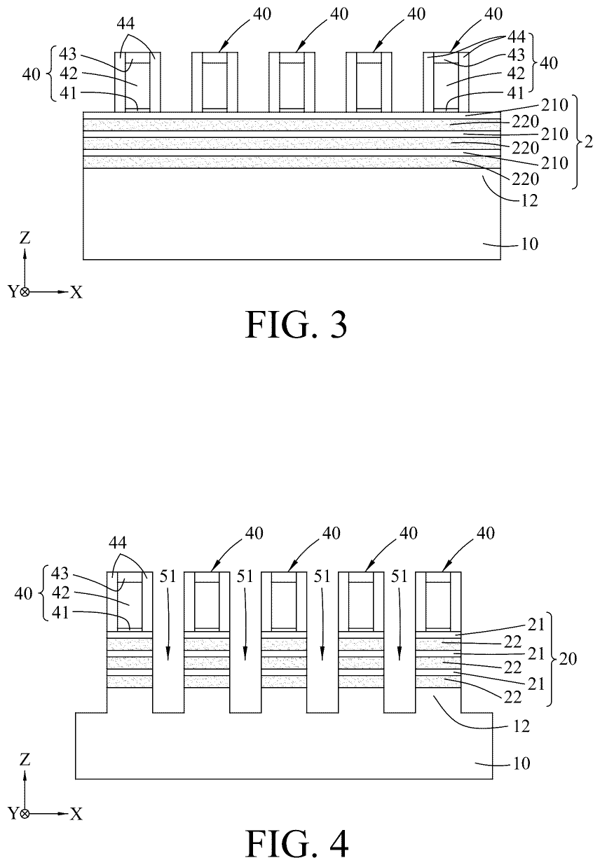

Referring to FIG. 3, step 101 may include a second sub-step of forming dummy stacks 40 each including a dummy gate dielectric 41, a dummy gate electrode 42 (collectively referred to as a dummy gate), and a hard mask 43. The dummy stacks 40 extend over the nanosheet material stacks 2 in the transverse direction (Y). The dummy stacks 40 are spaced apart from each other in the longitudinal direction (X) and are formed by: depositing first and second dummy layers (not shown) respectively for forming the dummy gate dielectric 41 and the dummy gate electrode 42 using any suitable deposition processes; performing a planarization process (e.g., CMP) to obtain a planar upper surface of the second dummy layer (i.e., a planarized second dummy layer); forming a third dummy layer (not shown) for forming the hard mask 43 on the planarized second dummy layer using any suitable deposition processes; and patterning the first dummy layer, the planarized second dummy layer and the third dummy layer using any suitable patterning processes and/or etching processes so as to obtain the dummy gate dielectric 41, the dummy gate electrode 42, and the hard mask 43. The dummy gate dielectric 41 may include a dielectric material, such as silicon oxide, or the likes. The dummy gate electrode 42 may include polycrystalline silicon, or the likes. The hard mask 43 may be a single layer structure, or a multi-layered structure. The hard mask 43 may include a dielectric material, such as silicon nitride, silicon oxide, silicon oxynitride, or the likes, or combinations thereof. Other suitable processes and materials for forming the dummy gate dielectric 41, the dummy gate electrode 42 and the hard mask 43 are within the contemplated scope of the present disclosure.

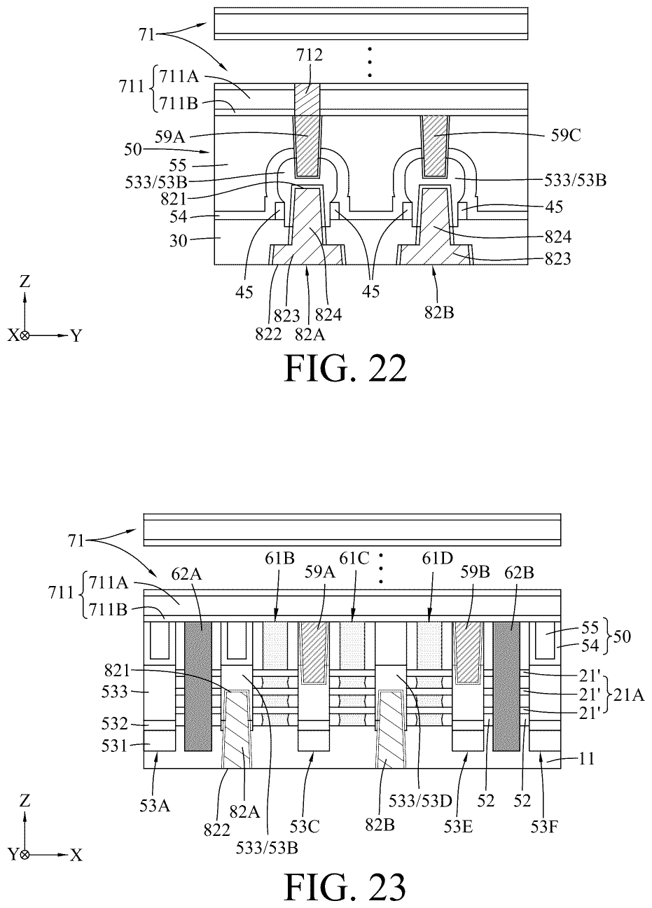

Afterwards, two gate spacers 44 are formed over the nanosheet material stacks 2 respectively on two sides of each of the dummy stacks 40 that are opposite to each other in the longitudinal direction (X). In some embodiments, the second sub-step further includes forming fin sidewall layers (not shown) which are at two opposite sides of each of the nanosheet material stacks 2, and which are patterned into fin sidewall portions 45 (see FIG. 22) after patterning the nanosheet material stacks 2 in a third sub-step of step 101. In some embodiments, a spacer material layer for forming the gate spacers 44 and the fin sidewall layers is deposited over the dummy stacks 40, the nanosheet material stacks 2 and the isolation elements 30 using any suitable deposition processes, and is patterned by any suitable patterning processes and/or etching processes. The gate spacers 44 and the fin sidewall layers may be made of a same or different material in a same or different processes, and may include a dielectric material, such as a silicon carbon-containing dielectric material, a silicon oxide-containing material, silicon nitride, other suitable materials, or combinations thereof. Other suitable processes and materials for forming the gate spacers 44 and the fin sidewall layers are within the contemplated scope of the present disclosure.

Referring to FIG. 4, step 101 may include a third sub-step of patterning each of the nanosheet material stacks 2 (see FIG. 3) into a plurality of nanosheet stacks 20, thereby obtaining source/drain recesses 51. The third sub-step in step 101 may be performed using a patterning process, which may include, as described in the foregoing, a photolithography process, followed by an etching process. The nanosheet stacks 20 are spaced apart from each other in the longitudinal direction (X). In some embodiments, the source/drain recesses 51 formed by patterning each of the nanosheet material stack 2 are further extended into a respective one of the fins 12. As shown in FIG. 4, the first nanosheet layers 210 (see FIG. 3) are patterned to form channel layers 21 of the nanosheet stacks 20, and the second nanosheet layers 220 are patterned to form sacrificial layers 22 of the nanosheet stacks 20. In some embodiments, in the third sub-step of step 101, the hard mask 43 and the gate spacers 44 are provided to protect the dummy gate dielectric 41 and the dummy gate electrode 42. Other suitable processes for forming the channel layers 21 and the sacrificial layers 22 are within the contemplated scope of the present disclosure.

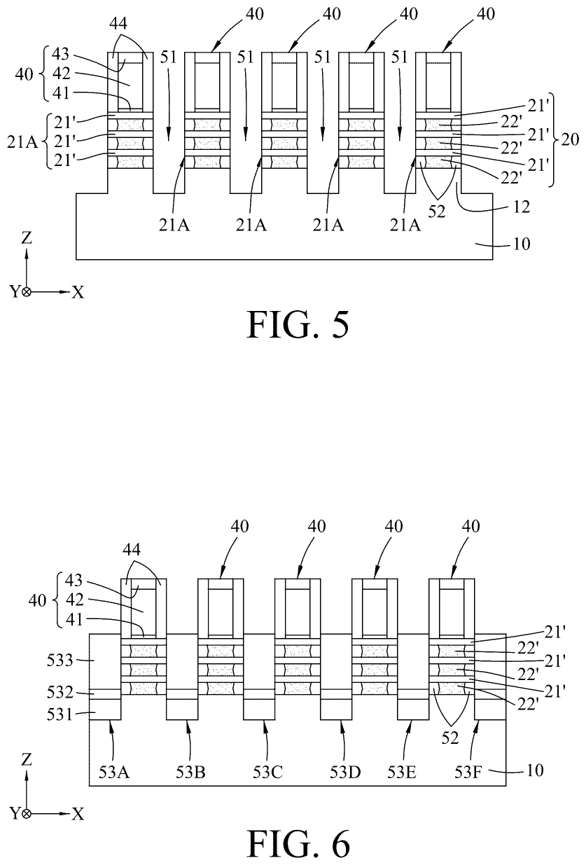

Referring to FIG. 5, step 101 may include a fourth sub-step of forming inner spacers 52. The fourth sub-step may include recessing end portions of the sacrificial layers 22 to form lateral recesses (not shown) using any suitable etching processes, and then forming the inner spacers 52 respectively in the lateral recesses using any suitable deposition processes and patterning processes. The inner spacers 52 may include a dielectric material such as silicon oxide, silicon nitride, silicon oxynitride, silicon carbide, or the likes, or combinations thereof. As shown in FIG. 5, the channel layers 21 are formed into channel features 21′ and the sacrificial layers 22 are formed into sacrificial features 22′. In other words, each two of the inner spacers 52 are disposed at two opposite sides of a respective one of the sacrificial features 22′. In some embodiments, the channel layers 21 are substantially not etched and thus have a configuration substantially the same that of the channel features 21'. Other suitable processes for forming the inner spacers 52 are within the contemplated scope of the present disclosure. In the following description, the number of the channel features 21′ in each of the nanosheet stacks 20 is exemplified as three, a plurality of channel portions 21A are respectively formed in the nanosheet stacks 20, and each of the channel portions 21A includes, in a direction toward the substrate 10, an uppermost one, a middle one and a bottommost one of the channel features 21′ (which may be also referred to as a distal channel feature (distal from the substrate 10), a middle channel feature, and a proximal channel feature (proximal to the substrate 10), respectively).

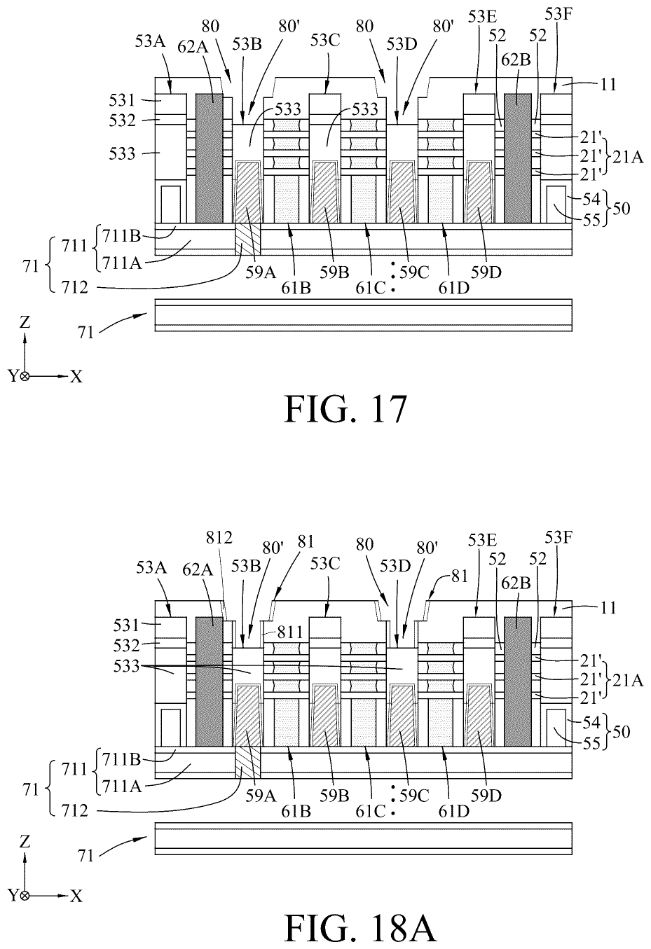

Referring to FIG. 6, step 101 may include a fifth sub-step of forming filling parts 53A, 53B, 53C, 53D, 53E and 53F which are respectively filled in the source/drain recesses 51 (see FIG. 5). Each of the filling parts 53A, 53B, 53C, 53D, 53E and 53F includes an epitaxial portion 531, an isolation portion 532 and a source/drain portion 533. In some embodiments, the epitaxial portion 531 is made of non-doped silicon, silicon germanium, or boron-doped silicon. In some embodiments, the epitaxial portion 531 is formed by an epitaxial growth process (such as molecular-beam epitaxy (MBE), selective area epitaxy (SAE), etc.), or other suitable deposition techniques. In some embodiments, the isolation portion 532 may serve as an etch stop layer during etching of back side of the substrate 10 to be described in subsequent step (see FIG. 17). In some embodiments, the isolation portion 532 may be made of a dielectric material, for example, but not limited to, silicon nitride, silicon oxide, silicon oxynitride, silicon carbon nitride, nitride-doped silicon oxide, silicon oxycarbide, a high-k material (e.g., aluminum oxide, hafnium oxide, hafnium silicates, hafnium silicon oxynitride, tantalum-doped hafnium oxide, hafnium titanate, zirconium-doped hafnium oxide, and the like), or combinations thereof. In some embodiments, the isolation portion 532 may be formed by a suitable deposition process, for example, but not limited to, CVD or ALD. Two ends of each of the channel features 21′ are connected to the source/drain portions 533 of two corresponding adjacent ones of the filling parts 53A, 53B, 53C, 53D, 53E and 53F, respectively. In some embodiments, the source/drain portion 533 may include single or multiple epitaxy layers. In certain embodiments, the source/drain portion 533 may include silicon, silicon germanium, other suitable materials, or combinations thereof. In other embodiments, the source/drain portion 533 may include any suitable dopants (such as n-type dopant(s), or p-type dopant(s)). In certain embodiments, the source/drain portion 533 may be formed using, e.g., an epitaxy growth process, but is not limited thereto. Other suitable materials and/or processes for forming the epitaxial portion 531, the isolation portion 532, and the source/drain portion 533 are within the contemplated scope of the present disclosure.

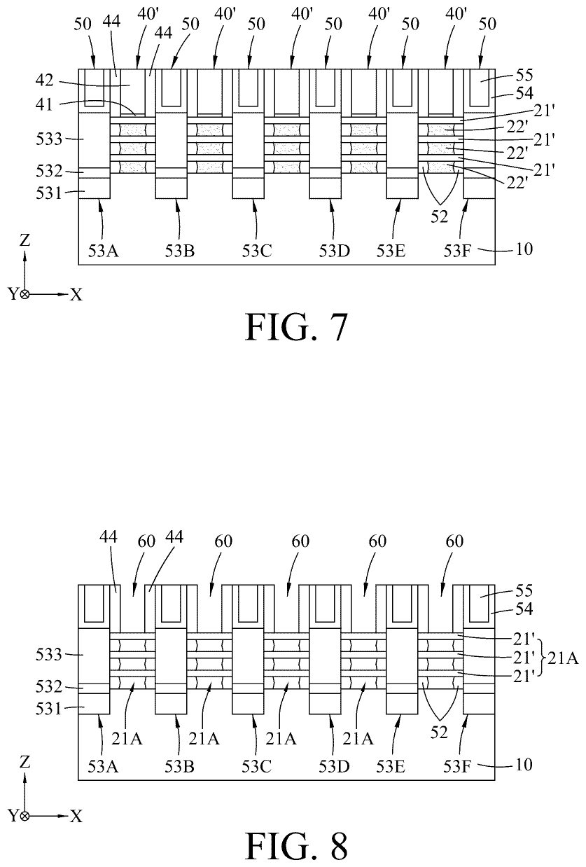

Referring to FIG. 7, step 101 may further include a sixth sub-step of sequentially forming dielectric structures 50 each of which is formed over the source/drain portion 533 of a respective one of the filling parts 53A, 53B, 53C, 53D, 53E and 53F and each of which includes a contact etch stop layer (CESL) 54 and an interlayer dielectric (ILD) 55. The dielectric structures 50 are formed by depositing two dielectric material layers respectively for forming the CESL 54 and the ILD 55 over the structure shown in FIG. 6 using any suitable disposition processes, followed by removing an excess of the two dielectric material layers using a planarization process (e.g., CMP) to remove the hard masks 43 of the dummy stacks 40 (see FIG. 6), thereby exposing the dummy gate electrode 42, accordingly. After the sixth sub-step of step 101, the dummy stacks 40 are referred to as remaining dummy stacks 40'. Each of the CESL 54 and each of the ILD 55 may include a dielectric material such as silicon oxide, silicon nitride, phosphosilicate glass, borophosphosilicate glass, spin-on glass, fluorosilicate glass, carbon-doped silicon oxide, xerogel, aerogel, parylene, divinylsiloxane-bis-benzocyclobutene-based dielectric material, polyimide, or the like, or combinations thereof. The CESL 54 and the ILD 55 may include different dielectric materials. Other suitable materials and processes for forming the CESL 54 and the ILD 55 are within the contemplated scope of the present disclosure. As shown in FIG. 22, each of the dielectric structures 50 is also formed over corresponding ones of the isolation elements 30.

Referring to FIG. 8, step 101 may include a seventh sub-step, where the dummy gate, i.e., the dummy gate dielectric 41 and the dummy gate electrode 42, of each of the remaining dummy stacks 40', and the sacrificial features 22′ are removed (see FIG. 7), so as to form cavities 60 that will accommodate active gates 61A, 61B, 61C, 61D and 61E formed in subsequent step (see FIG. 9). The dummy gate and the sacrificial features 22′ may be removed using any suitable etching processes. Other suitable processes for removing the dummy gate and the sacrificial features 22′ are within the contemplated scope of the present disclosure.

Referring to FIG. 9, step 101 may include an eighth sub-step, where the active gates 61A, 61B, 61C, 61D and 61E are formed to fill the cavities 60, respectively.

FIG. 10 is an enlarged sectional view of the active gate 61C taken from the boxed region (L) of the patterned structure 1 shown in FIG. 9 in accordance with some embodiments. As shown in FIG. 10, each of the active gates 61A, 61B, 61C, 61D and 61E, which is exemplified by the active gate 61C, includes a gate dielectric 611 and a gate electrode 612. The gate dielectric 611 may include a high dielectric constant material, such as a hafnium-based dielectric material, or the like, but is not limited thereto. The gate electrode 612 may include titanium nitride (TiN), tantalum nitride (TaN), titanium silicon nitride (TiSiN), tungsten carbon nitride (WCN), molybdenum (Mo), titanium aluminum (TiAl), titanium aluminum carbide (TiAlC), titanium aluminum silicon carbide (TiAl(Si)C), tantalum aluminum carbide (TaAlC), tantalum aluminum silicon carbide (TaSiAlC), or the likes, or combinations thereof, but are not limited thereto. Other suitable materials for the gate dielectric 611 and the gate electrode 612 are within the contemplated scope of the present disclosure. In some embodiments, the gate dielectric 611 and the gate electrode 612 may be formed by sequentially depositing materials for forming the gate dielectric 611 and the gate electrode 612 using any suitable deposition processes (e.g., CVD or ALD), followed by removing an excess of the materials using a planarization process (e.g., CMP) to expose the dielectric structures 50. Other suitable techniques for forming the active gates 61A, 61B, 61C, 61D and 61E are within the contemplated scope of the present disclosure. After the eighth sub-step of step 101, the patterned structure 1 (see FIG. 9) is obtained accordingly.

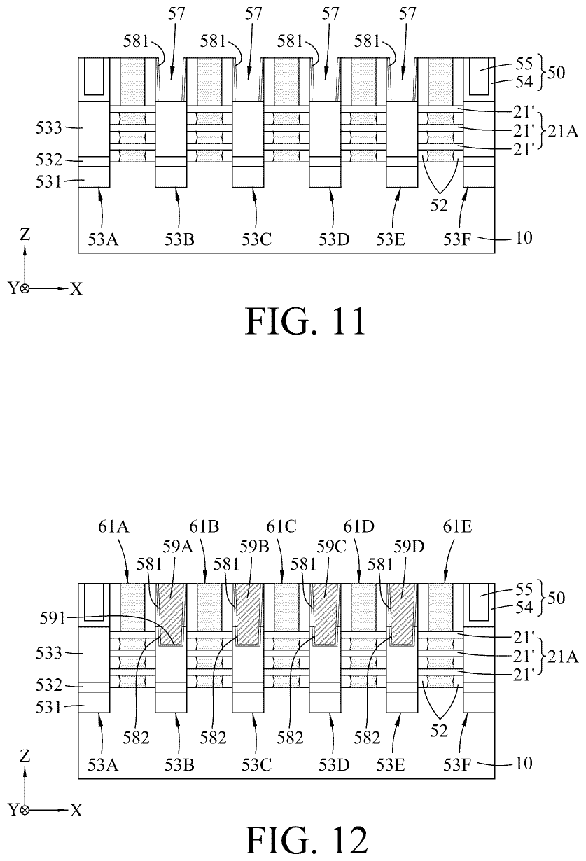

Referring to FIG. 1 and the examples illustrated in FIGS. 11 to 13, the method 100 proceeds to step 102, where front source/drain contacts 59A, 59B, 59C and 59D (see FIG. 12, which may be also referred to as front contacts) are respectively formed to extend into the source/drain portions 533 of the filling parts 53B, 53C, 53D and 53E. Step 102 may include several sub-steps as described hereinafter.

Referring to FIG. 11, a first sub-step of step 102 may include forming protection portions 581 by patterning the dielectric structures 50 (see FIG. 9) using a patterning process to form recesses 57 (through which front surfaces of the source/drain portions 533 of the filling parts 53B, 53C, 53D and 53E are exposed). To be specific, a protection material layer (not shown) is conformally formed over the structure obtained after forming the recesses 57 using, for example, but not limited to, CVD, and then an excess of the protection material layer is selectively removed using, for example, but not limited to, anisotrophic etching, thereby leaving the protection portions 581 respectively on inner sidewall surfaces of the recesses 57. The protection portions 581 are made of any suitable dielectric materials. In some embodiments, the protection portions 581 are made of silicon nitride and may be referred to as silicon nitride redeposition (SNR) portions. Other suitable materials and processes for forming the recesses 57 and the protection portions 581 are within the contemplated scope of the present disclosure.

A second sub-step of step 102 may include performing another etching process for further deepen the recesses 57, such that each of the deepened recesses (not shown) further extends into the source/drain portions 533 of a respective one of the filling parts 53B, 53C, 53D and 53E, until each of the deepened recesses extends over a level of an uppermost one of the channel features 21′.

Referring to FIG. 12, a third sub-step of step 102 may include filling a conductive material in the deepened recesses using, for example, but not limited to, ALD, CVD, plating, or other suitable techniques, followed by removing an excess of the conductive material using, e.g., CMP or other suitable techniques, thereby obtaining the front source/drain contacts 59A, 59B, 59C and 59D. The conductive material for forming the front source/drain contacts 59A, 59B, 59C and 59D may include, for example, but not limited to, tungsten (W), aluminum (Al), ruthenium (Ru), cobalt (Co), copper (Cu), palladium (Pd), nickel (Ni), platinum (Pt), a low resistivity metal constituent, or the like, or combinations thereof. Other suitable materials and processes for forming the front source/drain contacts 59A, 59B, 59C and 59D are within the contemplated scope of the present disclosure. In some embodiments, a distance between the substrate 10 and a proximal surface 591 of at least one of the front source/drain contacts 59A, 59B, 59C and 59D is less than a distance between the substrate and a proximal surface of the uppermost one of the channel features 21′ of each of the channel portions 21A.

In some embodiments, metal silicide portion 582 may be formed between the source/drain portion 533 of each of the filling parts 53B, 53C, 53D and 53E, and a corresponding one of the front source/drain contacts 59A, 59B, 59C and 59D for reducing a contact resistance (Rcsd) between the source/drain portion 533 and the corresponding front source/drain contact 59A, 59B, 59C or 59D. In some embodiments, the metal silicide portion 582 may include titanium silicide, ruthenium silicide, nickel silicide, cobalt silicide, molybdenum silicide, or combinations thereof. The metal silicide portion 582 may be formed by depositing a metal layer (not shown) over the structure obtained after forming the deepened recesses, and performing a treatment to allow a portion of the metal layer to react with silicon elements in the source/drain portions 533 of the filling parts 53B, 53C, 53D and 53E, followed by removing an unreacted portion of the metal layer. Other suitable materials and processes for forming the metal silicide portions 582 are within the contemplated scope of the present disclosure.

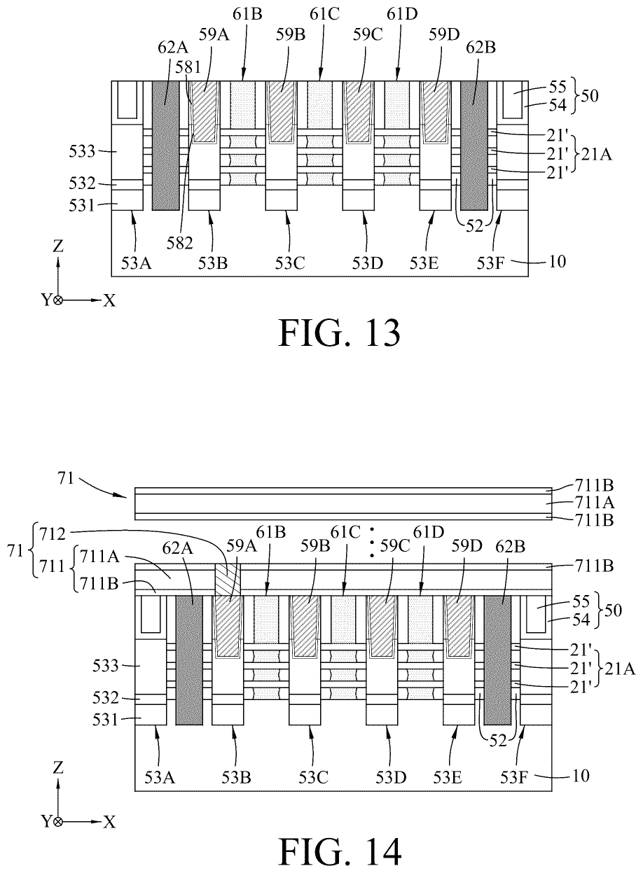

Referring to FIG. 13, a fourth sub-step of step 102 may include forming isolation features 62A, 62B in the structure shown in FIG. 12. To be specific, formation of the isolation features 62A, 62B may include performing a patterning process to remove the active gates 61A, 61E (see FIG. 12) and corresponding ones of the channel features 21′ which are wrapped by the active gates 61A, 61E until front portions of the fin 12 beneath the active gates 61A, 61E are partially removed so as to form trenches (not shown), and performing a depositing process to deposit a dielectric material for forming the isolation features 62A, 62B such that the dielectric material fills the trenches, followed by a planarization process, for example, but not limited to, CMP, to remove an excess of the dielectric material for forming the isolation features 62A, 62B. In some embodiments, the dielectric material for forming the isolation features 62A, 62B may include, but not limited to, silicon oxide, carbon-doped silicon oxide, which may be also referred to as silicon oxycarbide), silicon nitride, or combinations thereof. Other suitable materials and processes for the isolation features 62A, 62B are within the contemplated scope of the present disclosure. After step 102, a front end of line (FEOL) portion of the semiconductor structure is obtained.

Referring to FIG. 1 and the example illustrated in FIG. 14, the method 100 proceeds to step 103, where a back end of line (BEOL) portion is formed on the FEOL portion. The BEOL portion includes interconnect features 71 stacked on each other in the vertical direction (Z). Each of the interconnect features 71 includes a dielectric portion 711 and conductive portions 712 (one of the conductive portions 712 is exemplied as a contact via in FIG. 14) formed in the dielectric portion 711. In certain embodiments, the dielectric portion 711 includes a low-k dielectric material. In some embodiments, the dielectric portion 711 may include an intermetallic dielectric (IMD) layer 711A and an etch stop layer 711B which are made of different dielectric materials, such as silicon oxide, silicon oxycarbide, silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOC), spin-on-glass (SOG), fluorine-doped silicon oxide, carbon-doped silicon oxide, porous silicon oxide, porous carbon-doped silicon oxide, other suitable low-k dielectric materials, or combinations thereof. In some embodiments, the conductive portions 712 may be configured as conductive lines or conductive vias each of which is connected to the gate electrode 612 (see FIG. 10), the source/drain portion 533 or other suitable elements. In some embodiments, as shown in FIG. 14, the contact via 712, which is electrically connected to a front power routing (e.g., the Vdd or Vss for transmission of the supply voltage or the ground voltage), is electrically connected to the source/drain portion 533 of the filling part 53B through the front source/drain contact 59A. In this case, the source/drain portion 533 of the filling part 53B may serve as a source, and the source/drain portion 533 of the filling part 53C, which is adjacent to the source/drain portion 533 of the filling part 53B, may serve as a drain. The materials for forming the conductive portions 712 may be similar to those for forming the front source/drain contacts 59A, 59B, 59C and 59D as described with reference to FIG. 12, and the interconnect features 71 may be formed using any suitable damascene processes. Other suitable materials and processes for forming the interconnect features 71 are within the contemplated scope of the present disclosure.

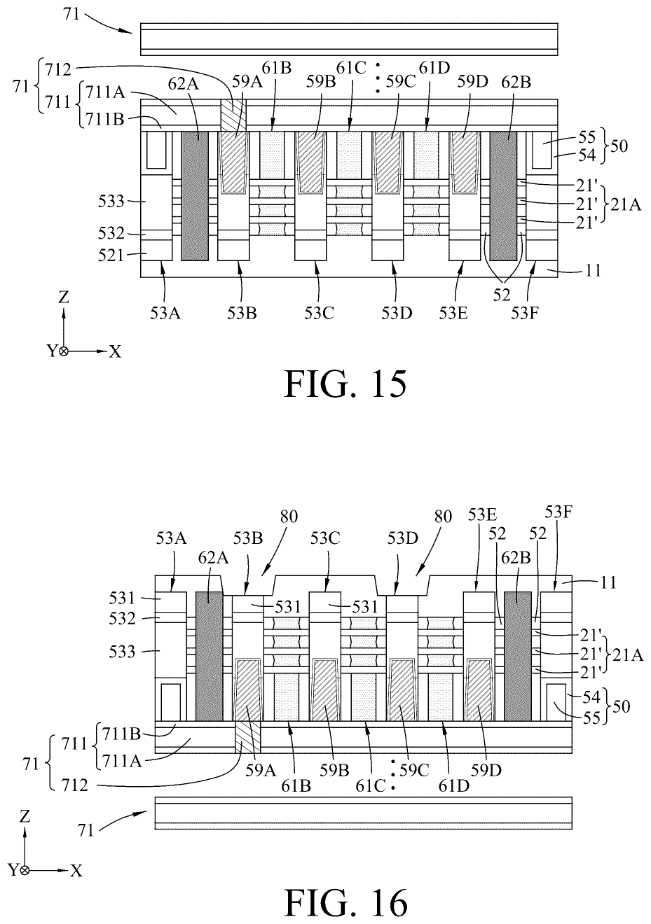

Referring to FIG. 1 and the example illustrated in FIG. 15, the method 100 proceeds to step 104, where the substrate 10 is thinned down from a back side thereof. In step 104, the substrate 10 is subjected to a polishing process (for example, CMP), an etching process or combinations thereof, such that the substrate 10 has a reduced thickness, as denoted by the numeral 11.

Referring to FIG. 1 and the examples illustrated in FIGS. 16 to 20, the method 100 proceeds to step 105, where back side vias 82A, 82B (see FIG. 20, which may be also referred to as back contacts) are formed on a back side of the substrate 11. It should be noted that the structures shown in FIGS. 16 to 20 are structures subsequent to that shown in FIG. 15, and the structures in FIGS. 16 to 20 are turned upside down (in the vertical direction (Z)) in comparison with the structure shown in FIG. 15 for easy illustration.

Referring to FIG. 16, step 105 may include a first sub-step of forming back openings 80 on the back side of the substrate 11 (see FIG. 15) using any suitable patterning processes and/or etching processes. After the first sub-step of step 105, the epitaxial portions 531 of the filling parts 53B, 53D are respectively exposed from the back openings 80.

Referring to FIG. 17, step 105 may include a second sub-step of sequentially removing the epitaxial portions 531 and the isolation portions 532 of the filling parts 53B, 53D to expose of the source/drain portions 533 of the filling parts 53B, 53D using any suitable patterning processes or etching processes, thereby obtaining first extended openings 80′ which extend respectively from the back openings 80. As shown in FIG. 17, in certain embodiments, each of the first extended openings 80′ has a width measured in the longitudinal direction (X) that is less than a width of each of the back openings 80.

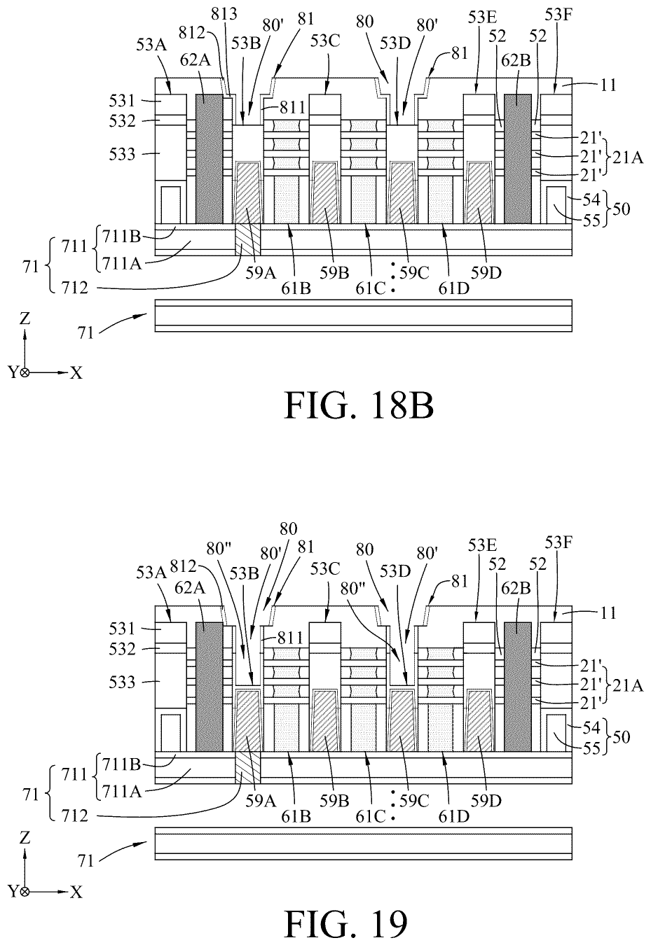

Referring to FIG. 18A, step 105 may include a third sub-step of forming protection portions 81 each of which includes a first protection region 811 formed on an inner sidewall of a respective one of the first extended openings 80', and a second protection region 812 formed on an inner sidewall of a respective one of the back openings 80. The materials and processes for forming the protection portions 81 may be similar to those for forming the protection portions 581 as described above in step 102 with reference to FIG. 11. In other embodiments, as shown in FIG. 18B, each of the protection portions 81 may further include a third protection region 813 interconnecting the first protection region 811 and the second protection region 812. Other suitable materials and processes for forming the protection portions 81 are within the contemplated scope of the present disclosure. For purposes of simplicity and clarity, only the structure shown in FIG. 18A is used to illustrate the following sub-steps.

Referring to FIG. 19, step 105 may include a fourth sub-step of forming second extended openings 80″ which extend respectively from the first extended openings 80′ into the source/drain portions 533 of the filling parts 53B, 53D using any suitable patterning processes and/or etching processes. In some embodiments, each of the second extended openings 80″ extends from the respective first extended opening 80′. In certain embodiments, as shown in FIG. 19, a distance between the substrate 11 and a distal surface of each of the second extended openings 80″ may be substantially same as a distance between the substrate and a distal surface of the middle one of the channel features 21′ of a corresponding adjacent one of the channel portions 21A.

Referring to FIG. 20, step 105 may include a fifth sub-step of forming metal silicide portions 814 respectively in the second extended openings 80″ (see FIG. 19), and then filling a conductive material in the second extended openings 80″, the first extended openings 80′ and the back openings 80 using, for example, but not limited to, ALD, CVD, plating, or other suitable techniques, followed by conducting a planarization process, for example, but not limited to, CMP, to remove an excess of the conductive material, thereby obtaining the semiconductor structure having the back side vias 82A, 82B. In certain embodiments, the metal silicide portions 814 each may include one silicide layer. In other embodiments, the metal silicide portions 814 each may include multiple silicide layers. The materials and processes for forming the metal silicide portions 814 may be similar to those for forming the metal silicide portions 582 as described above in step 102 with reference to FIG. 12. The conductive material for forming the back side vias 82A, 82B may be similar to the conductive material for forming the front source/drain contact 59A, 59B, 59C and 59D as described in step 102. Other suitable materials and processes for forming the back side vias 82A, 82B are within the contemplated scope of the present disclosure.

In some embodiments, multiple silicide layers (e.g., one of the metal silicide portions 814 and a respective one of the metal silicide portions 582), which are in contact with each other, are formed between each of the back side vias 82A, 82B and a respective one of the front source/drain contacts 59A, 59C.

In certain embodiments, in a cross-section view (i.e., X-cut view) of the semiconductor structure shown in FIG. 20 or a cross-section view (i.e., Y-cut view) of the semiconductor structure shown in FIG. 22, each of the back side vias 82A, 82B is T-shaped, and has a base region 823 formed in the substrate 11, and an extended region 824 extending from the base region 823 into the source/drain portion 533 of a corresponding one of the remaining filling parts 53B, 53D. Each of the base region 823 and the extended region 824 has a width measured in the longitudinal direction (X) or the transverse direction (Y), and the width of the base region 823 is larger than the width of the extended region 824. A distance between the substrate 11 and a distal surface 821 of each of the back side vias 82A, 82B is larger than a distance between the substrate 11 and a distal surface of a bottommost one of the channel features 21′ (i.e., the distal surface of the proximal channel feature 21′). In some embodiments, as shown in FIGS. 20 and 22, the distance between the substrate 11 and the distal surface 821 of each of the back side vias 82A, 82B is not less than a distance between the substrate 11 and a proximal surface of a middle one of the channel features 21′ and is not greater than a distance between the substrate 11 and a distal surface of the middle one of the channel features 21′. In some embodiments, a distances between each of the front source/drain contacts 59A, 59C and a respective one the back side vias 82A, 82B is less than a distance between two adjacent ones of the channel features 21′ in the vertical direction (Z). Since the back side vias 82A, 82B may have a relatively wide dimension, parasitic resistance from each of the back side vias 82A, 82B to the uppermost one of the channel features 21′ (i.e., the distal channel feature 21′) of a corresponding one of the channel portions 21A (see also FIG. 8) can be effectively reduced. In some embodiments, as shown in FIG. 20, each of the back side vias 82A, 82B is connected to a back power routing, and the respective one of the front source/drain contacts 59A, 59C is connected to the front power routing, and thus the supply or ground voltage is transmitted to the source/drain portion 533 of a respective one of filling parts 53B, 53D from two opposite sides thereof. As such, the parasitic resistance from the back side via 82A or 82B to all of the channel features 21′ of the corresponding channel portion 21A may be minimized. It should be noted that a back side routing density in the substrate 11, in which the back side vias 82A, 82B are formed, is lower than a front side routing density in the dielectric structures 50 (see FIG. 20), in which the front source/drain contacts 59A, 59B, 59C and 59D are formed, because the dimension of each of the front source/drain contacts 59A, 59B, 59C and 59D is limited by a space between two corresponding adjacent ones of the active gates 61A, 61B, 61C, 61D and 61E. Therefore, the back side vias 82A, 82B may have a relatively wide dimension due to the relaxed back side routing. In some embodiments, a maximum width (first width) of the back side via 82A or 82B, measured in the longitudinal direction (X) or the transverse direction (Y), may be about 1.2 times to about 5 times a maximum width (second width) of the front source/drain contact 59A, 59B, 59C or 59D, measured in the longitudinal direction (X) or the transverse direction (Y). For example, the first width may be, e.g., about 1.2 times to about 2 times the second width, about 1.5 times to about 3 times the second width, about 2 times to about 3.5 times the second width, about 2.5 times to about 4 times the second width, about 3 times to about 4.5 times the second width, or about 3.5 times to about 5 times the second width. In some embodiments, the first width is substantially same as a maximum width of the base region 823, and the second width is less than or substantially same as a maximum width of the extended region 824.

In certain embodiments not shown, a front contact (e.g., the front source/drain contact 59A, 59B, 59C or 59D) formed on a front side of the substrate 11 may have a first height measured in the vertical direction (Z), a back contact (e.g., the back side via 82A or 82B) extending from a back side of the substrate 11 into the structure formed on the front side of the substrate 11 may have a second height measured in the vertical direction (Z). In certain embodiments, the first height is larger than the second height, and a value of a ratio of the first height to the second height ranges from about 1 to about 10. In other embodiments, the first height is less than the second height, and a value of a ratio of the first height to the second height ranges from about 0.1 to about 1.

FIG. 21 is a layout diagram illustrating a position relationship among the active gates 61B, 61C and 61D, the front source/drain contacts 59A, 59B, 59C and 59D, the isolation features 62A, 62B, and the back side vias 82A, 82B in accordance with some embodiments. FIG. 20 shows a schematic cross sectional view taken along line A-A of FIG. 21 in accordance with some embodiments. FIG. 22 shows a schematic cross sectional view taken along line B-B of FIG. 21 in accordance with some embodiments.

As shown in FIG. 22, a distance between the substrate 11 and the distal surface 821 of each of the back side vias 82A, 82B is larger than a distance between the substrate 11 and the distal surface of a corresponding adjacent one of the isolation elements 30. A distance between the distal surface 821 of each of the back side vias 82A, 82B and the distal surface of the corresponding adjacent one of the isolation elements 30 ranges from about 5 nm to about 30 nm. The two source/drain portions 533 shown in FIG. 22 may have the same or different conductivity types. In some embodiments, a cross-section (X-cut view) of each of the back side vias 82A, 82B taken in the longitudinal direction (X), as shown in FIG. 20, is T-shaped, and a cross-section (Y-cut view) of each of the back side vias 82A, 82B taken in the transverse direction (Y), as shown in FIG. 22, is T-shaped. In some other embodiments, only one of the X-cut view and the Y-cut view of each of the back side vias 82A, 82B is T-shaped.

In some embodiments, some steps in the method 100 may be modified, replaced, or eliminated without departure from the spirit and scope of the present disclosure. In some alternative embodiments, the semiconductor structure may further include additional features, and/or some features present in the semiconductor structure may be modified, replaced, or eliminated without departure from the spirit and scope of the present disclosure.

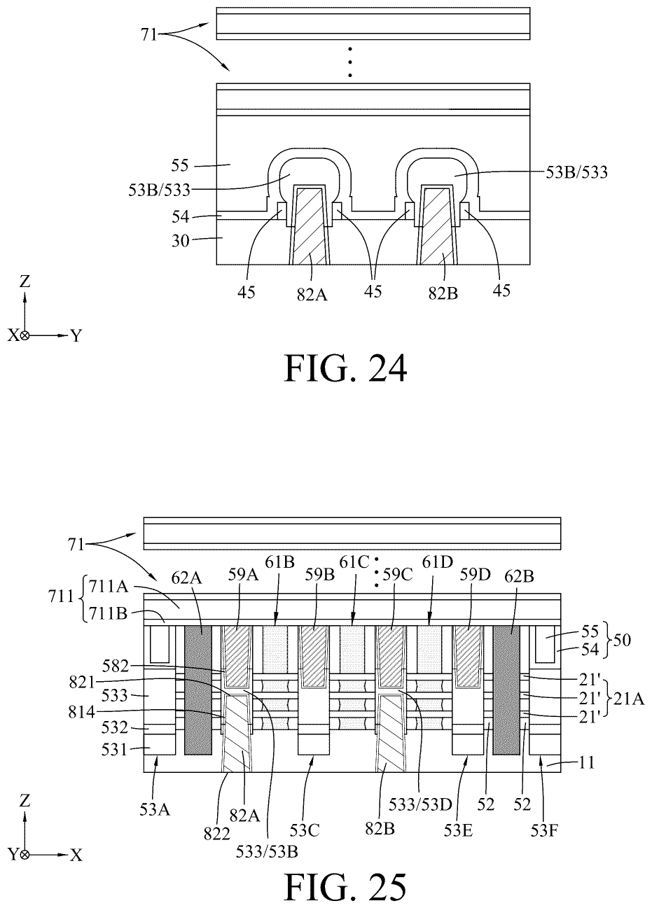

For example, the semiconductor structures shown in FIGS. 23 to 28 are other alternative embodiments. FIGS. 23 and 24 are respectively an X-cut view and a Y-cut view of the semiconductor structure in accordance with some embodiments. The semiconductor structure shown in FIGS. 23 and 24 differs from the semiconductor structure shown in FIGS. 20 and 22 in the following features: (i) the contact via 712 to be connected to the front power routing (see FIGS. 20 and 22) is not formed (i.e., the supply voltage or ground voltage is only supplied from the back power routing), (ii) each of the back side vias 82A, 82B has a tapered rectangular shape without a base region 823, and (iii) the front source/drain contacts 59A, 59C shown in FIG. 20 are omitted. In some embodiments, as shown in FIGS. 23 and 24, both the X-cut view and the Y-cut view of each of the back side vias 82A, 82B is the tapered rectangular shape.

The semiconductor structure shown in FIG. 25 differs from the semiconductor structure shown in FIG. 20 in the following features: (i) the contact via 712 to be connected to the front power routing (see FIG. 20) is not formed (i.e., the supply voltage or ground voltage is only supplied from the back power routing), and (ii) each of the back side vias 82A, 82B has a tapered rectangular shape without a base region.

In certain embodiments, as shown in FIGS. 23 and 25, each of the back side vias 82A, 82B has a back surface 822 that that is flush with the back surface of the substrate 11 and that has a width of a first value (measured in the longitudinal direction (X) or the transverse direction (Y)) which ranges from about 15 nm to about 30 nm. The distal surface 821 of each of the back side vias 82A, 82B has a width of a second value (measured in the longitudinal direction (X) or the transverse direction (Y)) that is less than the first value. A difference (a third value) between the first value and the second value ranges from about 2 nm to about 6 nm. In certain embodiments, a ratio of the third value to the first value may range from about 1:3 to about 1:5. In certain embodiments, when the ratio of the third value to the first value is less than 1:3, parasitic resistance from the back side via 82A or 82B to the corresponding one of the channel portions 21A might not be effectively reduced. In certain embodiments, when the ratio of the third value to the first value is greater than 1:5, other issues (e.g., increased parasitic capacitance) might occur.

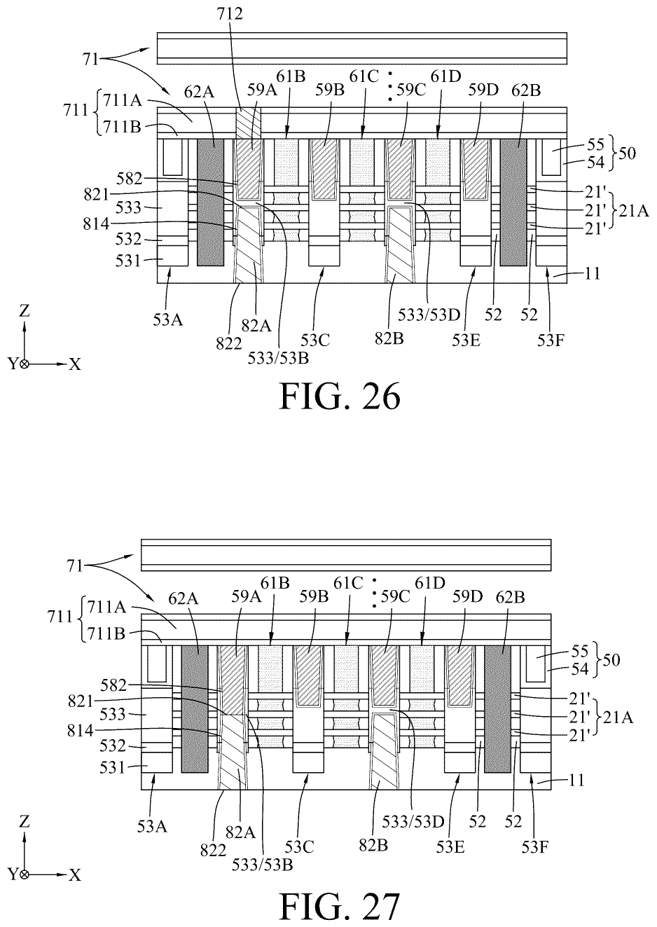

The semiconductor structure shown in FIG. 26 is substantially similar to that shown in FIG. 25, except that in the semiconductor structure shown in FIG. 26, a contact via 712 to be connected to the front power routing (which is also formed in FIG. 20) is formed.

The semiconductor structure shown in FIG. 27 is substantially similar to that shown in FIG. 25, except that in the semiconductor structure shown in FIG. 27, the front source/drain contact 59A touches and is in contact with the back side via 82A, such that the channel features 21′ adjacent thereto receive substantially same amount of electrical voltage, thereby increasing device stability.

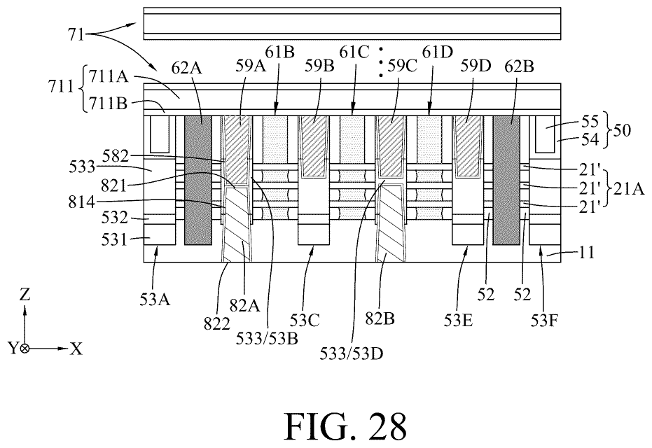

The semiconductor structure shown in FIG. 28 is substantially similar to that shown in FIG. 27, except that in the semiconductor structure shown in FIG. 28, the metal silicide portion 814, which is formed between the source/drain portion 533 of the filling part 53B and the back side via 82A, touches and is in contact with the metal silicide portion 582, which is formed between the source/drain portion 533 of the filling part 53B and the front source/drain contact 59A. In other words, a first silicide layer 582 formed around the front source/drain contact 59A and a second silicide layer 814 formed around the back side via 82A are in contact with each other.

The embodiments of the present disclosure have the following advantageous features. By forming the back side via which has a relatively large contact area with the source/drain portion, parasitic resistance at the source/drain portion can be reduced, and front side BEOL metal routing resource can be increased, thereby enhancing performance of the semiconductor structure.

In accordance with some embodiments of the present disclosure, a method for manufacturing semiconductor structure includes: forming a channel portion including a distal channel feature and a proximal channel feature which are spaced apart from each other on a front side of a substrate, the distal channel feature and the proximal channel feature being distal from and proximal to the substrate, respectively, each of the distal channel feature and the proximal channel feature having a distal surface and a proximal surface relative to the substrate; forming a first source/drain portion and a second source/drain portion which are respectively disposed at two opposite sides of the channel portion; forming a first front contact which extends into the first source/drain portion through a front surface of the first source/drain portion; and forming a back contact which extends into the second source/drain portion through a back surface of the second source/drain portion, the back contact having a distal surface relative to the substrate. A first distance between the substrate and the distal surface of the back contact is greater than a second distance between the substrate and the distal surface of the proximal channel feature.

In accordance with some embodiments of the present disclosure, the channel portion further includes a middle channel feature which is located between the distal channel feature and the proximal channel feature, and which has a distal surface and a proximal surface relative to the substrate.

In accordance with some embodiments of the present disclosure, the first distance is not less than a distance between the substrate and the proximal surface of the middle channel feature.

In accordance with some embodiments of the present disclosure, the first distance is not greater than a distance between the substrate and the distal surface of the middle channel feature.

In accordance with some embodiments of the present disclosure, the back contact has a base region formed in the substrate, and an extended region extending from the base region into the second source/drain portion. Each of the base region and the extended region has a width. The width of the base region is larger than the width of the extended region.

In accordance with some embodiments of the present disclosure, a maximum width of the back contact is 1.2 times to 5 times a maximum width of the first front contact.

In accordance with some embodiments of the present disclosure, the back contact further has a back surface which is flush with a back surface of the substrate, and which has a width of a first value that ranges from 15 nm to 30 nm.

In accordance with some embodiments of the present disclosure, the distal surface of the back contact has a width of a second value that is less than the first value, and a difference between the first value and the second value ranges from 2 nm to 6 nm.

In accordance with some embodiments of the present disclosure, the method further includes forming a second front contact which extends into the second source/drain portion through a front surface of the second source/drain portion.

In accordance with some embodiments of the present disclosure, the distal channel feature and the proximal channel feature are spaced apart from each other in a vertical direction. A length of the first front contact measured in the vertical direction is different from a length of the second front contact measured in the vertical direction.

In accordance with some embodiments of the present disclosure, the first source/drain portion is a drain portion, and the second source/drain portion is a source portion.

In accordance with some embodiments of the present disclosure, the first front contact has a distal surface and a proximal surface relative to the substrate, and a distance between the substrate and the proximal surface of the first front contact is less than a distance between the substrate and the proximal surface of the distal channel feature.

In accordance with some embodiments of the present disclosure, a method for manufacturing a semiconductor structure includes: forming a first source/drain portion and a second source/drain portion on a front side of a substrate, the first source/drain portion and the second source/drain portion being spaced apart from each other by channel features; forming a front contact which extends into the first source/drain portion through a front surface of the first source/drain portion; and forming a back contact which extends into the first source/drain portion through a back surface of the first source/drain portion such that a distance between the front contact and the back contact is less than a distance between two adjacent ones of the channel features.

In accordance with some embodiments of the present disclosure, at least one silicide layer is formed between the front contact and the back contact.

In accordance with some embodiments of the present disclosure, a first silicide layer formed around the front contact and a second silicide layer formed around the back contact are in contact with each other.

In accordance with some embodiments of the present disclosure, the front contact and the back contact are in contact with each other.

In accordance with some embodiments of the present disclosure, the method further includes forming a protection portion in the substrate so as to separate the back contact from the substrate, the protection portion being made of a dielectric material.

In accordance with some embodiments of the present disclosure, a semiconductor structure includes a fin formed on a front side of a substrate; a channel portion formed on the fin opposite to the substrate, and including a distal channel feature and a proximal channel feature which are spaced apart from each other on a front side of a substrate, each of the distal channel feature and the proximal channel feature having a distal surface and a proximal surface relative to the substrate; a first source/drain portion and a second source/drain portion which are formed on the fin and are respectively disposed at two opposite sides of the channel portion; and a back contact which extends into the first source/drain portion through a back surface of the first source/drain portion. The back contact has a distal surface relative the substrate. A first distance between the substrate and the distal surface of the back contact is greater than a second distance between the substrate and the distal surface of the proximal channel feature.

In accordance with some embodiments of the present disclosure, the semiconductor structure further includes two isolation elements formed on the substrate and disposed at two opposite sides of the fin. Each of two isolation elements has a distal surface opposite to the substrate. A third distance between the substrate and the distal surface of each of the two isolation elements is less than the first distance.

In accordance with some embodiments of the present disclosure, a fourth distance between the distal surface of the back contact and the distal surface of each of the isolation elements ranges from 5 nm to 30 nm.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a channel portion including a distal channel feature and a proximal channel feature which are spaced apart from each other on a front side of a substrate, the distal channel feature and the proximal channel feature being distal from and proximal to the substrate, respectively, each of the distal channel feature and the proximal channel feature having a distal surface and a proximal surface relative to the substrate;
forming a first source/drain portion and a second source/drain portion which are respectively disposed at two opposite sides of the channel portion;
forming a first front contact which extends into the first source/drain portion through a front surface of the first source/drain portion; and
forming a back contact which extends into the second source/drain portion through a back surface of the second source/drain portion, the back contact having a distal surface relative to the substrate,
a first distance between the substrate and the distal surface of the back contact being greater than a second distance between the substrate and the distal surface of the proximal channel feature.

2. The method as claimed in claim 1, wherein the channel portion further includes a middle channel feature which is located between the distal channel feature and the proximal channel feature, and which has a distal surface and a proximal surface relative to the substrate.

3. The method as claimed in claim 2, wherein the first distance is not less than a distance between the substrate and the proximal surface of the middle channel feature.

4. The method as claimed in claim 2, wherein the first distance is not greater than a distance between the substrate and the distal surface of the middle channel feature.

5. The method as claimed in claim 1, wherein the back contact has a base region formed in the substrate, and an extended region extending from the base region into the second source/drain portion, each of the base region and the extended region having a width, the width of the base region being larger than the width of the extended region.

6. The method as claimed in claim 1, wherein a maximum width of the back contact is 1.2 times to 5 times a maximum width of the first front contact.

7. The method as claimed in claim 1, wherein the back contact further has a back surface which is flush with a back surface of the substrate, and which has a width of a first value that ranges from 15 nm to 30 nm.

8. The method as claimed in claim 7, wherein
the distal surface of the back contact has a width of a second value that is less than the first value, and
a difference between the first value and the second value ranges from 2 nm to 6 nm.

9. The method as claimed in claim 1, further comprising
forming a second front contact which extends into the second source/drain portion through a front surface of the second source/drain portion.

10. The method as claimed in claim 9, wherein the distal channel feature and the proximal channel feature are spaced apart from each other in a vertical direction, a length of the first front contact measured in the vertical direction being different from a length of the second front contact measured in the vertical direction.

11. The method as claimed in claim 1, wherein the first source/drain portion is a drain portion, and the second source/drain portion is a source portion.

12. The method as claimed in claim 1, wherein
the first front contact has a distal surface and a proximal surface relative to the substrate, and
a distance between the substrate and the proximal surface of the first front contact is less than a distance between the substrate and the proximal surface of the distal channel feature.

13. A method for manufacturing a semiconductor structure, comprising:
forming a first source/drain portion and a second source/drain portion on a front side of a substrate, the first source/drain portion and the second source/drain portion being spaced apart from each other by channel features;
forming a front contact which extends into the first source/drain portion through a front surface of the first source/drain portion; and
forming a back contact which extends into the first source/drain portion through a back surface of the first source/drain portion such that a distance between the front contact and the back contact is less than a distance between two adjacent ones of the channel features.

14. The method as claimed in claim 13, wherein at least one silicide layer is formed between the front contact and the back contact.

15. The method as claimed in claim 13, wherein a first silicide layer formed around the front contact and a second silicide layer formed around the back contact are in contact with each other.

16. The method as claimed in claim 13, wherein the front contact and the back contact are in contact with each other.

17. The method as claimed in claim 13, further comprising
forming a protection portion in the substrate so as to separate the back contact from the substrate, the protection portion being made of a dielectric material.

18. A semiconductor structure, comprising:
a fin formed on a front side of a substrate;
a channel portion formed on the fin opposite to the substrate, and including a distal channel feature and a proximal channel feature which are spaced apart from each other on a front side of a substrate, each of the distal channel feature and the proximal channel feature having a distal surface and a proximal surface relative to the substrate;
a first source/drain portion and a second source/drain portion which are formed on the fin and are respectively disposed at two opposite sides of the channel portion; and
a back contact which extends into the first source/drain portion through a back surface of the first source/drain portion, the back contact having a distal surface relative the substrate,
a first distance between the substrate and the distal surface of the back contact being greater than a second distance between the substrate and the distal surface of the proximal channel feature.

19. The semiconductor structure as claimed in claim 18, further comprising
two isolation elements formed on the substrate and disposed at two opposite sides of the fin, each of two isolation elements has a distal surface opposite to the substrate,
a third distance between the substrate and the distal surface of each of the two isolation elements being less than the first distance.

20. The semiconductor structure as claimed in claim 19, wherein a fourth distance between the distal surface of the back contact and the distal surface of each of the isolation elements ranges from 5 nm to 30 nm.
